(19) United States
(12) Patent Application Publication
(10) Pub. No.: US 2008/0194107 A1
(43) Pub. Date: Aug. 14, 2008

(54) Method of manufacturing semiconductor device

(75) Inventors: Akira Mitsuiki, Kanagawa (JP); Atsuro Inada, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/068,305

(22) Filed: Feb. 5, 2008

(30) Foreign Application Priority Data
Feb. 8, 2007 (JP) 28888/2007

(51) Int. Cl. H01L 21/311

(52) U.S. Cl. 438/699; 257/E21.249

(57) ABSTRACT

The present invention aims to improve the controllability of dimensions at the time when a silicon substrate or a film formed on top of the silicon substrate is etched. For this purpose, a SiN film is formed so as to be in contact with the top of an element-forming surface of a silicon substrate, and the SiN film is selectively removed to form an opening portion. Then, a plasma processing is carried out on the element-forming surface of the silicon substrate to remove deposits attached on sidewalls of the opening portion formed in the SiN film. After that, the silicon substrate is selectively removed by using the SiN film as a mask to form a concave portion in the silicon substrate.

### BACKGROUND OF THE INVENTION

1. Field of the Invention

The present invention relates to a method of manufacturing a semiconductor device. More particularly, this invention relates to a technique for etching a silicon substrate or layers stacked up on top of the silicon substrate.

2. Description of Related Art

An element-isolation film used in an LSI is formed by burying an insulating film in an element-isolation trench formed in a silicon substrate. To form the element-isolation trench in the silicon substrate, the following method is generally employed. Firstly, a silicon dioxide film (SiO₂ film) and a silicon nitride film (SiN film) are stacked up on top of a silicon substrate, and, in some cases another film is formed on the silicon nitride film so as to serve as a hard mask for etching. Subsequently, a resist film having a predetermined pattern is formed on the hard-mask film. After that, the hard mask, the silicon nitride film, the silicon dioxide film, and a part of the surface of the silicon substrate are etched. In this way, an element-isolation trench is formed in the silicon substrate.

FIGS. 8A to 8C show an example of conventional ways of forming an element-isolation trench. FIGS. 8A to 8C are sectional views showing the process of forming an element-isolation trench in a silicon substrate using a resist mask.

Firstly, a SiO₂ film 221, a SiN film 223 and an organic anti-reflective film 227 are formed on top of a silicon substrate 201. Subsequently, a resist film 207 having a predetermined pattern is formed on top of the organic anti-reflective film 227 (FIG. 8A). By using the resist film 207 as a mask, the organic anti reflective film 227, the SiN film 223, the SiO₂ film 221, and the silicon substrate 201 are sequentially etched (FIG. 8B). Finally, the resist film 207 is removed to complete the formation of a concave portion 217, which is made to be an element-isolation trench (FIG. 8C).

FIGS. 9A to 9C show another example of conventional ways of forming an element-isolation trench. FIGS. 9A to 9C are sectional views showing the process of forming an element-isolation trench in a silicon substrate using a hard mask.

Firstly, a SiO₂ film 221, a SiN film 223, an amorphous carbon film 205 functioning as a hard mask, and an inorganic anti-reflective film 225 are stacked up on top of a silicon substrate 201. Subsequently, a resist film 207 having a predetermined pattern is formed on top of the inorganic anti-reflective film 225 (FIG. 9A). By using the resist film 207 as a mask, the inorganic anti-reflective film 225, and the amorphous carbon film 205 are etched. The resist film 207 is eliminated during the etching. Thereafter, by using the amorphous carbon film 205 as a mask, the SiN film 223, the SiO₂ film 221, and the silicon substrate 201 are sequentially etched (FIG. 9B). The inorganic anti-reflective film 225 is eliminated while the SiN film 223 is etched. Finally, the amorphous carbon film 205 is removed by ashing using O₂ plasma to complete the formation of a concave portion 217, which is made to be an element-isolation trench (FIG. 9C).

The above-described method for forming an element-isolation trench by using a hard mask is described, for example, in Japanese Patent Application Laid-open Publication No. 2000-200828.

The above-described method is an example of the method for forming an element-isolation trench in a silicon substrate. Such selective etching of a silicon substrate using a mask, however, is a method that is commonly employed to form a concave portion in a silicon substrate.

Japanese Patent Application Laid-open Publication No. Hei 5-109702 discloses a processing technique for a passivation film. Although the disclosed technique pertains to a technical field that is different from the present invention, the technique includes a processing of removing deposits by O₂ plasma carried out after the etching of a passivation film. In addition, Japanese Patent Application Laid-open Publication No. 2005-45176 discloses a technique for forming a wiring layer including a technique related to a polymer deposition film.

### SUMMARY

The inventors have examined a variety of conventional methods for forming a concave portion, and have discovered the difficulty, involved in some of the cases, in forming a concave portion with desired dimensions in a silicon substrate.

Then, the inventors have investigated the cause of the difficulty. The investigation revealed the following facts. When an opening portion is formed in a film, such as a SiN film, formed on top of a silicon substrate, deposits are attached on the sidewalls of the opening portion. The deposits act as a mask while the silicon substrate is etched. As a result, the removed region of the silicon substrate turns out to be smaller than the opening portion formed in the film. In addition, the ashing, when performed after the etching of the silicon substrate, removes the deposits attached on the sidewalls of the opening portion. As a result, a step is created in the sidewalls of the opening portion between the silicon-substrate portion of the sidewalls and the SiN-film portion thereof located above the silicon-substrate portion.

The findings of the inventors are described below by taking specific examples.

FIGS. 10A to 10C and 11A to 11B are sectional views describing the attachment of the deposits, which the inventors have found out.

Firstly, as shown in FIG. 10A, a SiN film 203, an amorphous carbon film 205 and a resist film 207 having a predetermined pattern are stacked up on top of a silicon substrate 201.

Subsequently, by using the resist film 207 as a mask, the amorphous carbon film 205 is patterned to form an opening portion 211 in a predetermined position (FIG. 10B). Thereafter, by using the resist film 207 and the amorphous carbon film 205 as a mask, the SiN film 203 is selectively etched to form an opening portion 215. The resist film 207 is eliminated during the etching. Deposits 213 are attached on the sidewalls of the opening portion 215 while the SiN film 203 is etched (FIG. 10C).

After that, by using the amorphous carbon film 205 and the SiN film 203 as a mask, the silicon substrate 201 is selectively etched to form a concave portion 217 (FIG. 11A). Then, the amorphous carbon film 205 is removed. In this event, the deposits 203 are also removed along with the amorphous carbon film 205 (FIG. 11B). In this way, a step 231 is formed between the silicon substrate 201 and the SiN film 203.

The example that has been described above is a case where the amorphous carbon film 205 is formed on top of the SiN film 203. Such a step 231 is formed also in a case where a resist film 207 is formed directly on top of a SiN film 203 with no amorphous carbon film 205 provided in between and where a concave portion 217 is then formed in a silicon substrate 201 following the above-described procedure.

FIGS. 12A to 12C are other sectional views describing the attachment of the deposits, which the inventors have found out.

As FIG. 12A shows, a SiO₂ film 221, a SiN film 223, an amorphous carbon film 205, an inorganic anti-reflective film 225, and a resist film 207 with a predetermined pattern are stacked up on top of a silicon substrate 201.

In this case, when the silicon substrate 201 is etched, the etching of the silicon substrate 201 is carried out by using, as a mask, not only the SiN film 223 but also the amorphous carbon film 205, which is to be a hard mask. The receding of the SiN film 223 is thus restrained.

Also in this case, deposits 213 are deposited on the sidewalls while the SiN film 223 is etched (FIG. 12B). The deposits 213, in turn, serve as a mask when the silicon substrate 201 is etched. As a consequence, a step 231 is formed at the interface between the silicon substrate 201, and SiN film 223 and the SiO₂ film 221 (FIG. 12C).

As has been described thus far, when a concave portion is formed in a silicon substrate, an inorganic film, such as a SiO₂ film and a SiN film, or a hard mask, such as one made of an amorphous carbon, is used as a mask. The inventors have found out that deposits are attached on the sidewalls of the opening portion of the mask when the mask is formed.

The inventors have investigated the ways of restraining the formation of the above-described step and thus improving the controllability of the dimensions of the concave portion. As a result of the investigation, the inventors have found out a way of improving the controllability of the above-mentioned dimensions in the etching of the silicon substrate. To accomplish the improvement, deposits attached on the sidewalls of the hard mask and of the inorganic film need to be removed by an additional process of plasma processing. This additional removal process needs to be carried out after the opening portion is formed in the hard mask and in the inorganic film that are made to be a mask. This additional removal process, however, needs to be carried out before the etching of the silicon substrate. With such a process of effectively removing the objects attached on the sidewalls of the hard mask and the inorganic film, the above-mentioned improved controllability can be accomplished.

According to the present invention, there is provided a method of manufacturing a semiconductor device comprising:

forming a first film on a substrate that has a first layer on a surface of the substrate,

forming an opening portion in the first film,

carrying out a plasma processing and thus removing deposits attached on sidewalls of the opening portion; and

removing selectively the first layer by using the first film as a mask after removing the deposits.

In the above-described method, the first layer may be either a part of the substrate or a second film formed over the substrate.

In addition, the substrate may be a silicon substrate.

When the first layer is a silicon substrate, the step of selectively removing the first layer is a step of selectively removing the silicon substrate to form a concave portion in the silicon substrate.

In the manufacturing method according to the aspect of the present invention, the deposits attached on the sidewalls of the opening portion are removed. The removal of the deposits is carried out after the opening portion is formed in the first film to be used as a mask, and before the concave portion is, formed in the first layer, such as the silicon substrate. The removal of deposits on the sidewalls of the opening portion is achieved by exposing the element-forming surface of the silicon substrate to plasma before the etching of the silicon substrate. With the deposits thus removed, the concave portion is prevented from being formed smaller than the dimensions of the opening portion formed in the first film. To put it other way, the concave portion can be formed with certainty so as to correspond precisely to the dimensions of the opening portion. Also prevented is the formation of a step between the sidewalls of the concave portion formed in the silicon substrate and the sidewalls of the opening portion formed in the first film. Accordingly, an improvement is achieved in the controllability of dimensions at the time when the concave portion is formed in the silicon substrate. As a consequence, even when a microscopic concave portion is formed in the silicon substrate, the microscopic concave portion can be formed with an excellent precision of dimensions.

When the above-mentioned configurations are arbitrarily combined, the combination also functions as an embodiment of the present invention. In addition, though the present invention is expressed as a method, the present invention can also be carried out in the form of an apparatus or the like.

As has been described thus far, according to the present invention, a concave portion can be formed in a silicon substrate with improved dimensional precision.

### BRIEF DESCRIPTION OF THE DRAWINGS

FIGS. 1A to 1C are sectional views showing a manufacturing process of a semiconductor device according to a first embodiment.

FIGS. 2A to 2C are sectional views showing the manufacturing process of a semiconductor device according to the first embodiment.

FIG. 3 is a sectional view showing the manufacturing process of a semiconductor device according to the first embodiment.

FIGS. 4A to 4C are sectional views showing a manufacturing process of a semiconductor device according to a second embodiment.

FIG. 5 is a sectional view showing the manufacturing process of a semiconductor device according to the second embodiment.

FIGS. 6A and 6B are sectional views showing the manufacturing process of a semiconductor device according to a third embodiment.

FIGS. 7A and 7B are sectional views showing the manufacturing process of a semiconductor device according to the third embodiment.

FIGS. 8A to 8C are sectional views showing a conventional manufacturing process of a semiconductor device.

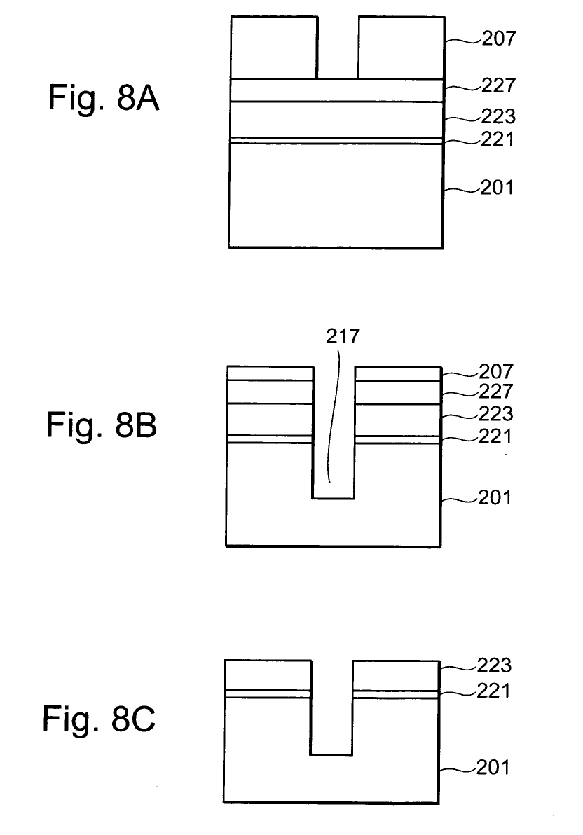

FIGS. 9A to 9C are sectional views showing the conventional manufacturing process of a semiconductor device.

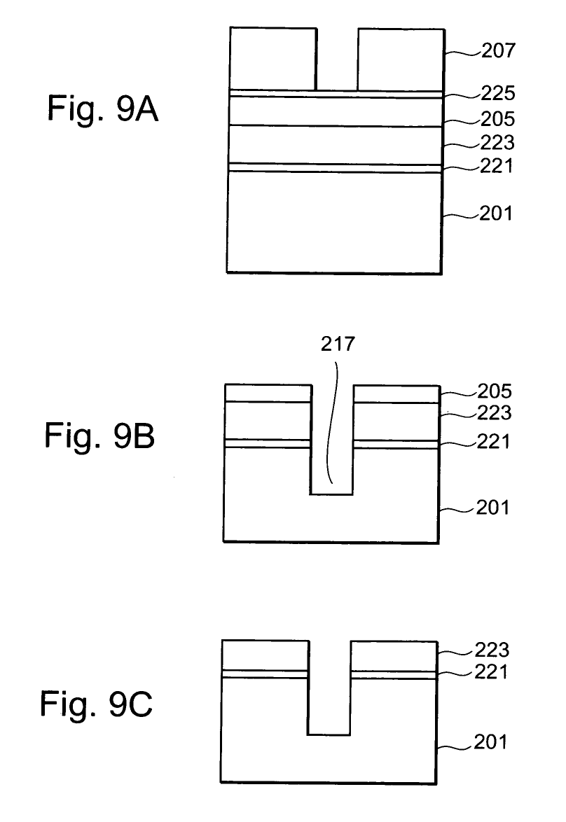

FIGS. 10A to 10C are sectional views showing a manufacturing process of a semiconductor device for describing what the inventors have found out.

FIGS. 11A and 11B are sectional views showing a manufacturing process of a semiconductor device for describing the findings of the inventors.

FIGS. 12A to 12C are sectional views showing a manufacturing process of a semiconductor device for describing the findings of the inventors.

### DETAILED DESCRIPTION OF THE PREFERRED EMBODIMENTS

Now, the present invention will be described in detail by way of embodiments with reference to the accompanying drawings. Note that the same reference numerals are used for identical component elements throughout all the drawings. Descriptions for these elements are omitted when such omission is possible.

### First Embodiment

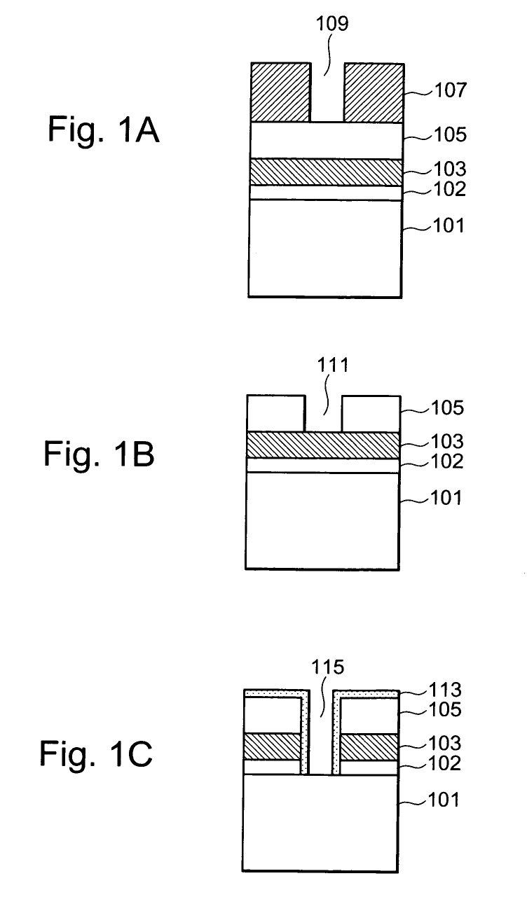

FIGS. 1A to 3 are sectional views showing a manufacturing process of a semiconductor device according to this embodiment.

The manufacturing process of a semiconductor device of this embodiment includes the following steps.

Firstly, as a first film, a film formed by stacking up a SiO₂ film 102 and a SiN film 103 in this order, for example, is stacked up on top of the element-forming surface of a substrate, such as a silicon substrate 101.

Secondly, an opening portion 115 is formed by selectively removing the SiO₂ film 102 and the SiN film 103.

Thirdly, the element-forming surface of the silicon substrate 101 in which the opening portion 115 is formed is exposed to plasma to remove deposits 113 attached on the sidewalls of the opening portion 115 during the step of forming the opening portion 115.

Finally, after the step of removing the deposits 113, the silicon substrate 101 is selectively removed by using both the SiO₂ film 102 and the SiN film 103 as a mask to form a concave portion 117.

In this case, a part of the silicon substrate 101 from the top surface down to a certain depth is designated as a first layer. To put it other way, a part of the silicon substrate 101 extending in the depth direction from the top of the element-forming surface to the bottom of the concave portion 117 is designated as the first layer. It is therefore possible to regard the step of selectively removing the silicon substrate 101 to form the concave portion 117 as a step of selectively removing the first layer.

These removing steps—the step of removing the SiO₂ film 102 and the SiN film 103, the step of removing deposits 113 and the step of removing silicon substrate 101—may be performed successively in the same plasma etching chamber. In this case, there is no wet process between these removing steps.

Now, each of the steps will be described more specifically with reference to FIGS. 1A to 3.

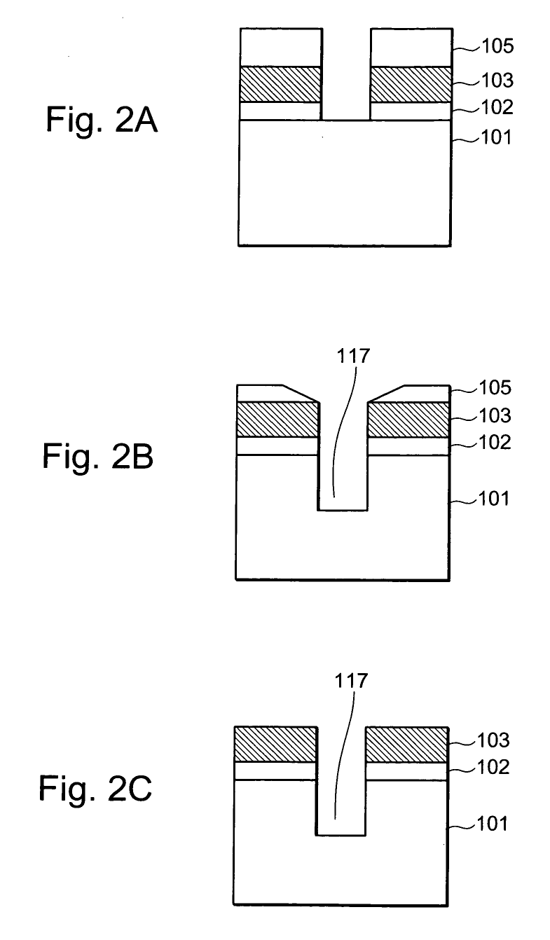

Firstly, as FIG. 1A shows, on top of the silicon substrate 101, the SiO₂ film 102 is formed so as to be in contact with the silicon substrate 101. Then, the SiN film 103, a film containing carbon—an amorphous carbon film 105, for example—and a resist film 107 are stacked up in this order on top of the SiO₂ film 102. Thereafter, the resist film 107 is patterned into a predetermined shape to form an opening portion 109 above a region where the concave portion 117 (which is not illustrated in FIGS. 1A to 1C, but is illustrated in FIG. 2B) is to be formed later.

Subsequently, by a dry etching process carried out by using the patterned resist film 107 as a mask, the amorphous carbon film 105 is patterned. Through this process, an opening portion 111 is formed at a predetermined position (FIG. 1B). A specific example of the gas used for etching the amorphous carbon film 105 includes a gas containing oxygen atoms, such as O₂. Alternatively, a dry etching process may be carried out here with oxygen radicals by generating plasma. The resist film 107 may be eliminated or may remain partially during the etching of the amorphous carbon film 105. Shown in this embodiment is a case where the resist film 107 is eliminated as FIG. 1B shows.

Subsequently, the SiN film 103 and the SiO₂ film 102 are successively dry-etched by using the amorphous carbon film 105, as a mask, with the opening portion 111 being formed therein. Thus, the opening portion 115 is formed in the SiN film 103 and in the SiO₂ film 102. As an example of the gas used for etching includes at least a gas whose molecule contains a carbon atom and a fluorine atom. To be more specific, at least one of fluorocarbon-based gases, such as CF₄, CHF₃, and CH₂F₂, is used.

Through the etching with these gases, the deposits 113 are attached on the sidewalls of the opening portion 115 formed in the SiN film 103 and in the SiO₂ film 102 (FIG. 1C). The deposits 113 are, presumably, polymers containing C, F, and Si as their constituent elements.

FIG. 1C shows an exemplar case where the attached deposits 113 extend from the top surface of the amorphous carbon film 105 all the way to the sidewalls of the opening portion 115. The deposits 113, however, may be attached on the bottom of the opening portion 115 under certain conditions for etching.

Subsequently, the attached deposits 113 are removed (FIG. 2A). Specifically, the removal of the deposits 113 is carried out by making the element-forming surface of the silicon substrate 101 be lightly subjected to a plasma processing. That is, the element-forming surface is exposed to plasma containing oxygen atoms. The plasma processing mentioned here only needs to be light one, because the removal of the deposits 113 that are deposited on the sidewalls of the SiN film 103 is the only thing that has to be achieved though the plasma processing. With such plasma processing, no step is formed between the silicon substrate 101 and the SiO₂ film 102 together with the SiN film 103. The plasma processing is carried out under the conditions of, for example, no bias power so that the etching can progress isotropically.

In this plasma processing for removing the deposits 113, the amount of plasma and its power are controlled so as to make the etching rate of the amorphous carbon film 105 be small and to make the removal of the deposits 113 be done sufficiently in a short period of time in comparison to the conditions for plasma ashing—to be described later—that is carried out to remove the amorphous carbon film 105.

The conditions for this plasma processing can be determined through experiments so as to be appropriate for the kind of gases to be used. To be more specific, for example, O₂ flow rate is set at 100 sccm, the source power is set at 300 W, and the pressure is set at 7 Pa.

In addition, to further improve the controllability of dimensions of the concave portion 117, the plasma processing is preferably carried out under the conditions that the amorphous carbon film 105 can be left, on the SiN film 103, in an enough thickness to function as a mask. It is more preferable that the plasma processing be carried out under the conditions that the degradation of the amorphous carbon film 105 can be slowed down. Furthermore, to slow down the decreasing of the thickness of the SiN film 103 and that of the SiO₂ film 102, the plasma processing is preferably carried out to the extent that the shape of the SiN film 103 and that of the SiO₂ film 104 after the silicon etching are not affected by the plasma processing.

Incidentally, the resist film 107 has already been removed by the time when the deposits 113 are removed. When the conditions for the plasma processing is expressed in terms of the etching amount of the resist film 107, the etching amount of the resist film 107 is preferably in a range from 5 nm to 30 nm, inclusive. With the plasma processing carried out under the conditions described above, the deposits 113 can be removed with more certainty, and, at the same time, the degradation of the amorphous carbon film 105 can be slowed down to the minimum.

Subsequently, the concave portion 117 is formed by selectively dry-etching the silicon substrate 101 through a mask composed of the SiO₂ film 102, the SiN film 103, and the amorphous carbon film 105 (FIG. 2B). The examples taken up in the descriptions of this embodiment and in those of the following embodiments are of cases in each of which the concave portion 117 serves as an element-isolation trench.

An example of the etching gas to be used for etching the silicon substrate 101 is a mixed gas in which at least one of gases containing halogen atoms, such as HBr, Cl₂, and SF₆ is mixed with at least any one of O₂ gas, N₂ gas, and He gas.

By the time when this etching is carried out, the deposits 113 have already been removed. Accordingly, the concave portion 117 can be formed with dimensions corresponding to the opening portion 115 that is formed in the SiN film 103 and in the SiO₂ film 102. As a consequence, no step is formed at the interface between the silicon substrate 101, and the SiN film 103 and the SiO₂ film 102.

Note that, as FIG. 2B shows, the amorphous carbon film 105 may be partially etched when the silicon substrate 101 is etched.

Subsequently, by plasma ashing, such as oxygen plasma ashing, the film that remains on top of the SiN film 103—the amorphous carbon film 105 in this case—is removed to make the top surface of the SiN film 103 be exposed (FIG. 2C). This plasma ashing is carried out under different conditions from those under which the above-described plasma processing for removing the deposits 113 is carried out. For example, the conditions for the plasma ashing include: an O₂ flow rate of 3 slm; a microwave power of 3 kW; and a pressure of 200 Pa.

The concave portion 117 formed in the silicon substrate 101 in the above-described way serves, for example, as an element-isolation trench. In this case, this trench is to be buried later with an insulating film. Thus, an element-isolation film 119 is formed. The way of forming the element-isolation film 119 will be described next.

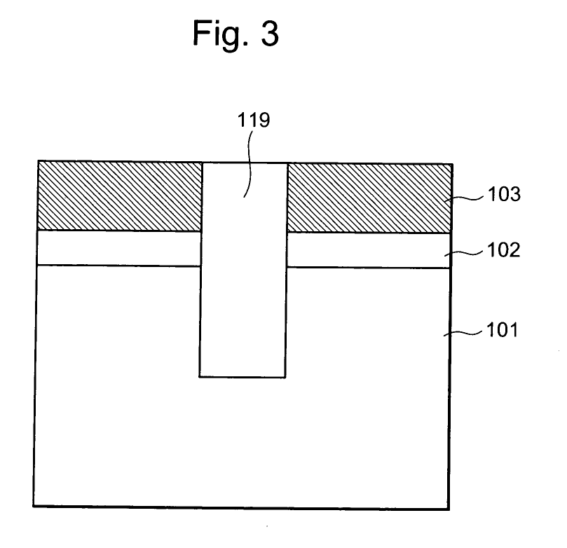

An insulating film that is to serve as the element-isolation film 119 is formed above the silicon substrate 101 so as to bury the concave portion 117 and to cover the SiN film 103 from above. An example of the element-isolation film 119 is a SiO₂ film. Such an insulating film can be formed by a CVD method. Then, as FIG. 3 shows, the insulating film that is formed outside the concave portion 117 is removed by chemical mechanical polishing (CMP) until the SiN film 103 is exposed. As a result, the element-isolation film 119 is formed so as to be buried in the concave portion 117. Here, the top surface of the element-isolation film 119 and the top surface of the SiN film 103 have approximately the same height.

Following the above-described procedure, a semiconductor device is obtained by a process according to this embodiment.

Note that a wet-etching may be carried out after the above-described procedure so as to remove the SiN film 103. In addition, a predetermined element, such as a transistor, may thereafter be formed in the element-forming region of the silicon substrate 101.

Subsequently, advantageous effects of this embodiment will be described.

In this embodiment, the deposits 113 attached on the sidewalls of the opening portion 115 of the SiN film 103 and the SiO₂ film 102 are removed by a plasma processing carried out after the etching of the SiN film 103 and SiO₂ film 102 both of which function as a mask for etching the silicon substrate 101 and before the etching of the silicon substrate 101. The concave portion 117 is thus formed exactly with the same dimensions with which the opening portion 115 is formed in the SiN film 103 and in the SiO₂ film 102. As a consequence, no step is formed at the interface between the silicon substrate 101 and the mask for etching the silicon substrate 101. In addition, the controllability of the shape and of the dimensions at the time of etching the silicon substrate 101 can be improved.

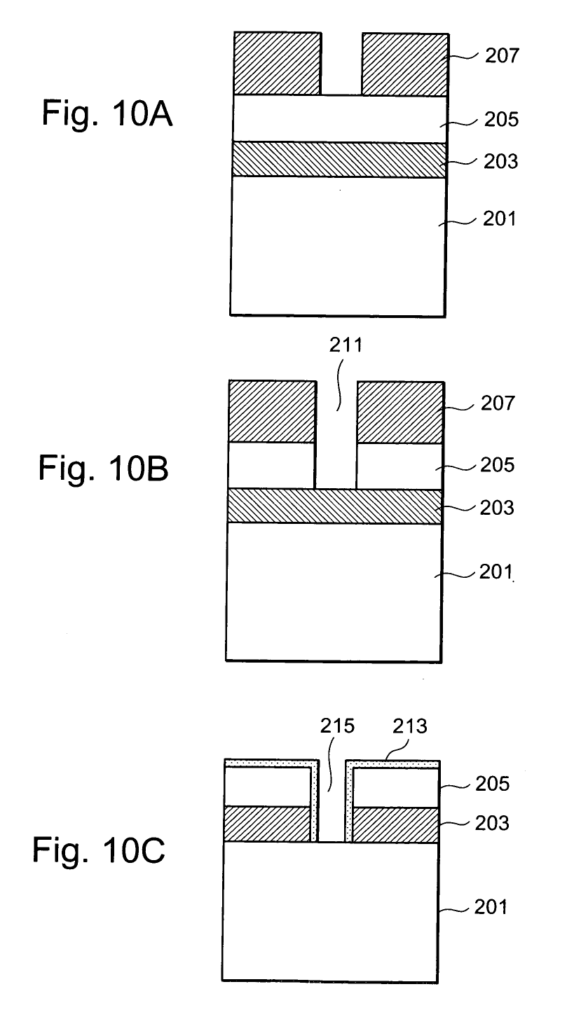

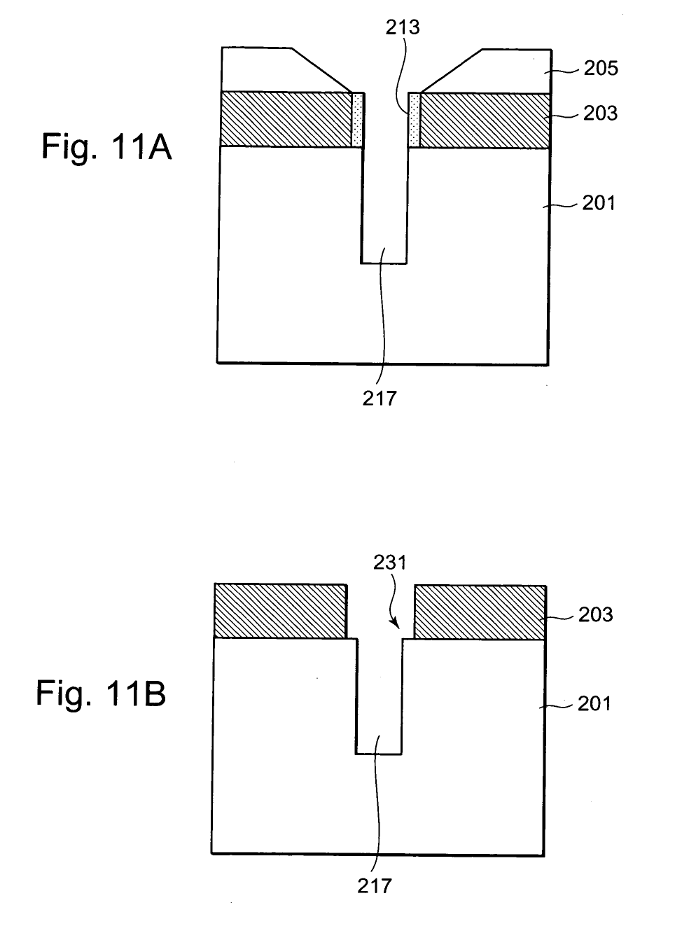

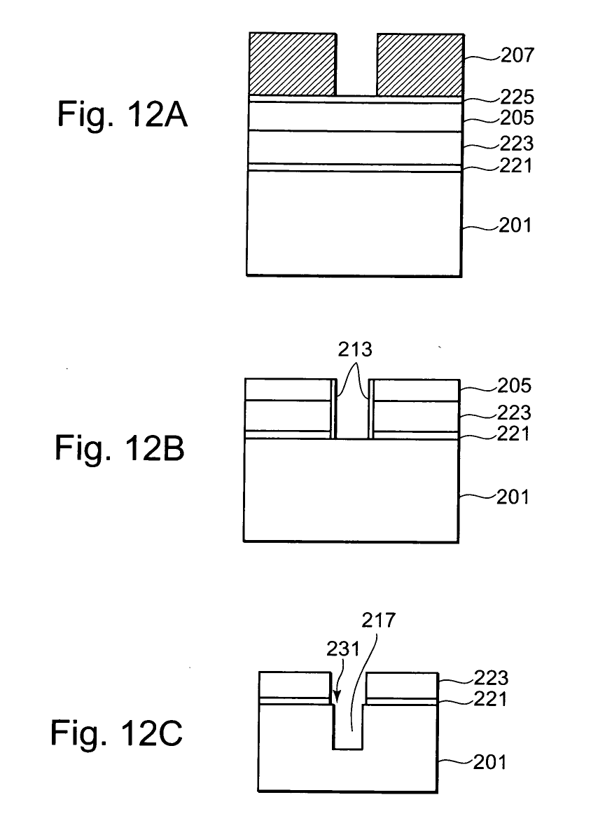

Now, refer to FIGS. 10A to 12C. As has been described above, also in the case where the amorphous carbon film 205 is allowed to remain on the mask for etching the silicon substrate 201, a step 231 is sometimes formed at the interface between the silicon substrate 201 and the mask for etching the silicon substrate 201. The formation of the step 231 is brought about by the difficulty in controlling the dimensions of the concave portion 217, which is formed in the silicon substrate 201.

By contrast, in this embodiment, the deposits 113 attached on the sidewalls of the opening portion 115 are removed before the concave portion 117 is formed in the silicon substrate 101. Accordingly, the deposits 113 are prevented from serving as a mask for forming the step around the interface between the silicon substrate 101, and the SiN film 103 and the SiO₂ film 102. As a consequence, such a step is not actually formed in this embodiment.

Moreover, in this embodiment, after the etching of the SiN film 103 and the SiO₂ film 102, a plasma processing is carried out to remove the deposits 113 while the amorphous carbon film 105 still remains. As a consequence, the controllability in the etching process for forming the concave portion 117 can further be improved.

In the following descriptions of other embodiments, what differentiates these embodiments from the first embodiment will be mainly focused upon.

### Second Embodiment

In the example taken up in first embodiment, the Si-containing films 102 and 103, the amorphous carbon film 105 and the resist film 107 are stacked up in this order on top of the silicon substrate 101. The amorphous carbon film 105 may not necessarily be formed. Specific descriptions follow in this respect.

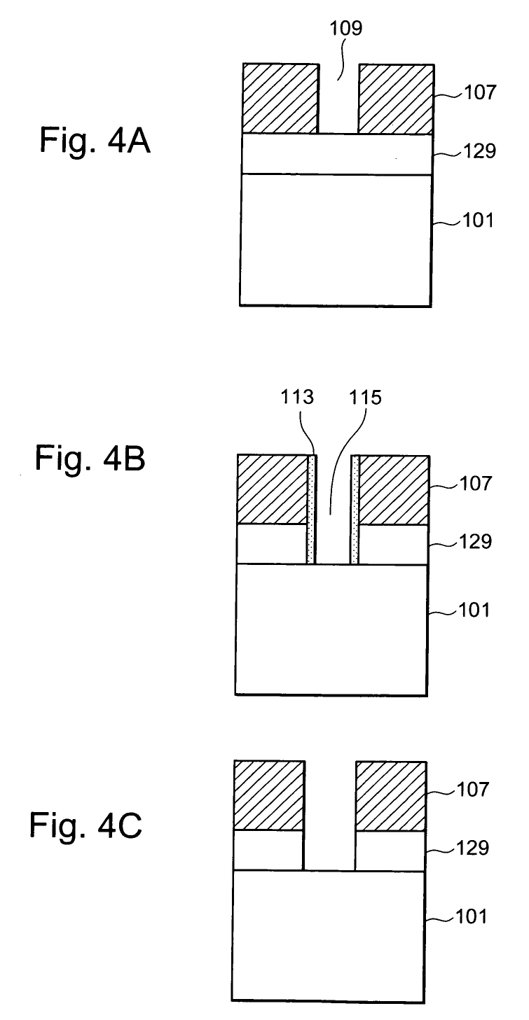

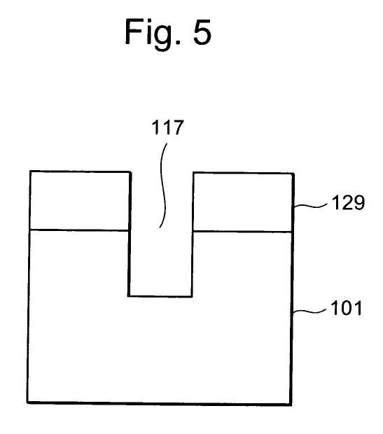

FIGS. 4A to 5 are sectional views showing the manufacturing process of a semiconductor device according to this embodiment.

In this embodiment, a SiN film 129 and a resist film 107, the two of which together function as a first film, are stacked up in this order on top of a silicon substrate 101.

Then, the resist film 107 is patterned into a predetermined shape to form an opening portion 109 (FIG. 4A). Thereafter, the SiN film 129 is selectively etched by using the resist film 107 as a mask to form an opening portion 115. After that, deposits 113 attached on the sidewalls of the opening portion 115 (FIG. 4B) are removed by a plasma processing (FIG. 4C). The plasma processing is carried out under the same conditions that are employed in the first embodiment. The conditions for plasma processing have to be controlled so as to make the amount of etching the resist film 107 within a range from 5 nm to 30 nm, inclusive. Note that FIG. 4B shows that the deposits 113 are attached on the sidewalls of the opening portion 115. The deposits 113, however, may also be attached on the top surface of the SiN film 129 and on the bottom of the opening portion 115.

Then, the silicon substrate 101 is selectively etched by using the resist film 107 and SiN film 129 as a mask to form a concave portion 117 in the silicon substrate 101 (FIG. 5).

Also in this embodiment, the element-forming surface of the silicon substrate 101 is exposed to plasma after the opening portion 115 is formed by etching the SiN film 129 and before the concave portion 117 is formed. Consequently, the same advantageous effects as those obtained in the first embodiment can be obtained in this embodiment.

### Third Embodiment

In the example taken up in the first embodiment, the Si-containing films 102 and 103, the amorphous carbon film 105 and the resist film 107 are stacked up in this order on top of the silicon substrate 101. An inorganic anti-reflective film made of an inorganic material may be formed on top of the amorphous carbon film 105. Specific descriptions follow in this respect.

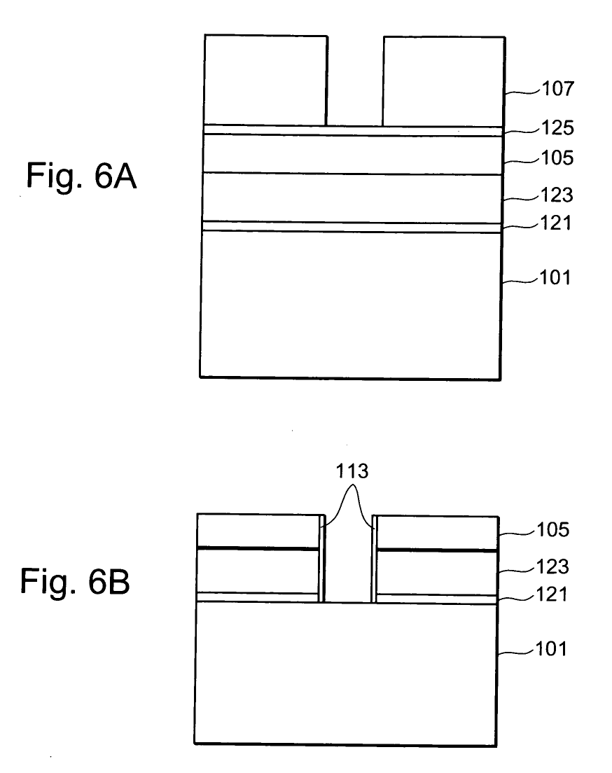

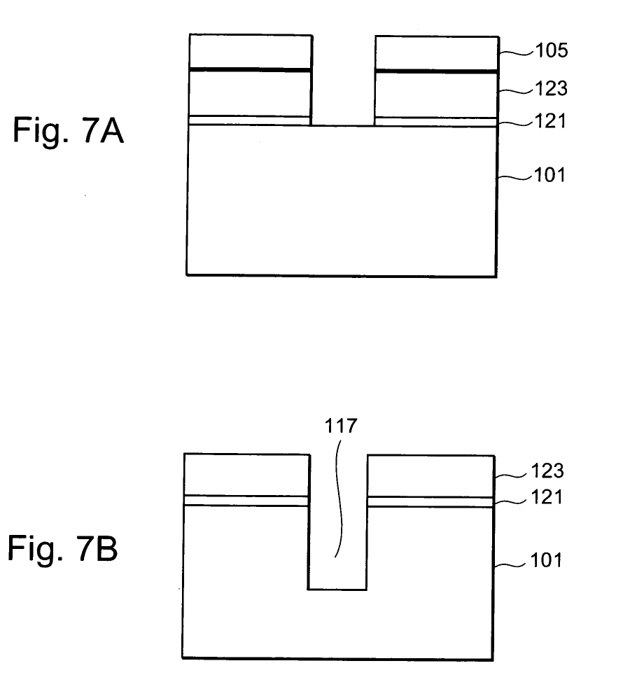

FIGS. 6A to 7B are sectional views showing the manufacturing process of a semiconductor device according to this embodiment.

Firstly, a SiO₂ film 121 is formed on top of a silicon substrate 101 in a thickness of, for example, 5 nm to 15 nm, and then, on top of the SiO₂ film 121, a SiN film 123 is formed in a thickness of, for example, 50 nm to 150 nm. On top of the SiN film 123, an amorphous carbon film 105 is formed in a thickness of, for example, 50 nm to 150 nm. On the top surface of the amorphous carbon film 105, an insulating film containing, for example, Si is formed in a thickness of, for example, 10 nm to 50 nm so as to be in contact with the top surface of the amorphous carbon film 105. The insulating film functions as an inorganic anti-reflective film 125. On top of the inorganic anti-reflective film 125, a resist film 107 is formed, and the resist film 107 is patterned into a predetermined shape (FIG. 6A).

Subsequently, the inorganic anti-reflective film 125 and the amorphous carbon film 105 is patterned by a dry-etching process with the resist film 107 used as a mask. The amorphous carbon film 105 is etched by a gas mainly containing O₂, for example. Accordingly, when the amorphous carbon film 105 is etched, the resist film 107 is removed. By contrast, the inorganic anti-reflective film 125, which is highly resistant to O₂ plasma, functions as an etching mask when the amorphous carbon film 105 is etched.

After the inorganic anti-reflective film 125 and the amorphous carbon film 105 are etched, these films 125 and 105 are used as a mask for the dry-etching of the SiN film 123 and the SiO₂ film 121 (FIG. 6B). In this dry-etching process, the inorganic anti-reflective film 125 is etched and removed. Also in this embodiment, while this etching is carried out, deposits 113 are attached on the sidewalls of the opening portion. Note that FIG. 6B shows that the deposits 113 are attached on the sidewalls of the opening portion. The deposits 113, however, may also be attached on the top surface of the amorphous carbon film 105 and on the bottom of the opening portion.

After that, a plasma processing is carried out with a gas which is capable of removing the deposits 113 but which etches none of the SiN film 123, the SiO₂ film 121, and the silicon substrate 101 (FIG. 7A). An example of such a gas is a gas containing at least one of the O₂, 03, N₂, H₂, and NH₃. The plasma processing is carried out to remove the deposits 113 that are deposited on the sidewalls of the SiN film 123. Accordingly, the plasma processing is carried out under the conditions of, for example, no bias power so that the etching can progress isotropically. In addition, the plasma processing is carried out to the extent that when expressed in terms of the etching amount of the resist film 107, the etching amount of the resist film 107 is within a range from 5 nm to 30 nm, inclusive. With the plasma processing carried out in this way, the diminishing of the amorphous carbon film 105, which serves as a hard mask, can be slowed down to the minimum. Furthermore, this plasma processing is preferably carried out to the extent that the shape of the SiN film 123 after the silicon etching is not affected by the plasma processing.

Subsequently, a concave portion 117 is formed by etching the silicon substrate 101 through a mask composed of the amorphous carbon film 105, the SiN film 123, and the SiO₂ film 121 (FIG. 2B). With this etching process, the silicon substrate 101 is etched from the top surface thereof down to the depth of 200 nm to 400 nm, for example. Also in this embodiment, by the time when this etching of the silicon substrate 101 is carried out, the deposits 113 that are deposited on the sidewall of the SiN film 123 and of the SiO₂ film 121 have already been removed. Accordingly, no step is formed at the interface between the silicon substrate 101, and the SiN film 123 and the SiO₂ film 121. Consequently, the same advantageous effects as those obtained in the first and the second embodiments can be obtained in this embodiment.

In addition, also in this embodiment, the plasma processing to remove the deposits 113 is carried out only lightly, so that the amorphous carbon film 105, which is to serve as a mask, can be allowed to remain with a sufficient thickness.

Incidentally, the width of an element-isolation film is getting smaller to a microscopic level. Accordingly, when an element-isolation trench is formed to prepare for the element-isolation film, the dimensions of the element-isolation trench have to be controlled with more precision, and the thickness of the SiN film 123 has to be secured sufficiently. As has been described above, the element-isolation film is formed by polishing an insulating film by CMP. Here, the insulating film, in general, tends to be polished down more rapidly than the SiN film 123. This is why use of the SiN film 123 with a small thickness as a stopper film at the CMP may sometimes result in the element-isolation film that is not high enough to reach the top surface of the silicon substrate 101.

The above-described example, the concave portion 117 formed in the silicon substrate 101 is used as an element-isolation trench. Besides, the concave portion 117 may be used, for example, to form a well therein. In this case, however, variation in the thickness of the SiN film 123 may possibly bring about a difficulty in forming, in the silicon substrate 101, a well that has a precisely desired depth.

To counter such possibility, in this embodiment, the deposits 113 are removed before the etching of the silicon substrate 101. In addition, the amorphous carbon film 105 and the inorganic anti-reflective film 125 are stacked up on top of the SiN film 123. With these measures, the diminishing of the thickness of the SiN film 123 after the etching can be reduced with more certainty. This contributes to an increase in the yielding when an element-isolation film or a well is formed in the concave portion 117 in a later step, and eventually to an increase in the yielding in the production of the semiconductor device as a whole.

An alternative way of removing the deposits 113 is use of a plasma ashing apparatus. The conditions for this plasma ashing, however, need to be set carefully. If the plasma ashing is carried out under the same conditions that are adopted to remove the resist film 107 or the amorphous carbon film 105, the amorphous carbon film 105, which is used as a mask, may possibly be removed and the SiN film 123 may possibly be exposed. For this reason, the plasma processing to remove the deposits 113 is preferably carried out under the conditions that can reduce the above-described diminishing of the thickness of the SiN film 123, and such conditions are different from those for the plasma ashing. To put it other way, the conditions to be employed here are preferably those for a light plasma processing.

Descriptions with reference to accompanying drawings have been provided for some embodiments of the present invention, but those descriptions are nothing more than examples of the present invention. Various other configurations than those described above can be employed to carry out the present invention.

For example, used as a first film, or a film that functions as a mask for the etching of the silicon substrate 101, is the laminated film of the SiO₂ film 102 and the SiN film 103 in the first embodiment, or the laminated film of the SiO₂ film 121 and the SiN film 123 in the third embodiment. In the second embodiment, the SiN film 129 alone serves for the same purpose. The materials of the mask used when the silicon substrate 101 is etched are not limited to those mentioned above. Examples of the mask for etching the silicon substrate 101 include silicon-containing films, such as a SiN film, a SiO₂ film, and a SiON film. These films may be used individually as a single-layer film, or a laminated film of some of these films may be used for the same purpose.

In addition, the example of a carbon-containing film used in the descriptions of the first and the third embodiments is an amorphous carbon film, which can also function as a hardmask. Alternatively, as a carbon-containing film, an organic film may replace the amorphous carbon film. Allowable organic film needs to be similar to an amorphous carbon film in the following points. The organic film has to be removed by an oxygen plasma ashing process, and there has to be selectivity, at the time of patterning, between the organic film and the resist film that is formed as a layer located above the organic film.

Moreover, the example of the first layer that is etched by using the first film as a mask in the above-described embodiments is a part of the top surface of the silicon substrate. The present invention is not limited to this example. Another example for the first layer may be a film formed on top of the substrate, and such a film is termed as a second film.

Examples of the second film include a polysilicon film. A polysilicon film is used, for example, as a film for the gate electrode, and is formed above the substrate with a gate oxide film provided in between. The first film, such as a SiN film, is formed on top of the polysilicon film. The SiN film functions as a mask for the etching of the polysilicon film. Subsequently, the SiN film is selectively etched by using a resist film with a predetermined pattern as a mask to form an opening portion in the SiN film. Then, deposits attached on the sidewalls of the opening portion formed in the SiN film are removed by plasma processing. After that, the polysilicon film is selectively etched by using this SiN film as a mask. Accordingly the polysilicon film can be etched exactly with the same dimensions with which the opening portion is formed in the SiN film. The gate electrode is thus formed with a high dimensional precision. Besides the polysilicon film, examples of a film to be the gate electrode include a metal silicide film, and a laminated film of a polysilicon film and a metal silicide film.

Furthermore, in the above-described embodiments, exposure to O₂ plasma is employed to remove the deposits 113 attached on the sidewalls of the opening portion formed in the SiO₂ film 102 or 121 and in the SiN film 103, 129, or 123. The gas used for the plasma processing is not limited to a gas containing oxygen atoms, such as O₂ and O₃. Other examples include N₂, H₂, and NH₃. In addition, the gas used for this purpose has only to contain at least any one of these gases, and the gas can be diluted with an inert gas when such dilution is necessary and appropriate.

Now, descriptions will be given for an example of the present invention and a comparative example.

### EXAMPLE

A semiconductor device was fabricated according to the method described in the third embodiment.

A SiO₂ film (10 nm), a SiN film (100 nm), an amorphous carbon film (100 nm), and an inorganic anti-reflective film (an insulating film containing Si, 30 nm) were stacked up on top of a silicon substrate.

Subsequently, a resist mask with a predetermined pattern was formed on top of the inorganic anti-reflective film, and then the inorganic anti-reflective film was dry-etched with CF₄ gas under a pressure of 5 mmTorr.

After that, plasma was generated by using a mixture gas of O₂ gas and HBr gas, and the amorphous carbon film was dry-etched with the plasma. During this dry-etching process, the mask formed on top of the inorganic anti-reflective film was dry-etched and thus removed. Meanwhile, the inorganic anti-reflective film was hardly removed.

Thereafter, the SiN film and the SiO₂ film were dry-etched. CHF₃ gas was used as the etching gas, and the pressure was set at 50 mmTorr.

With this etching process, the inorganic anti-reflective film was removed. In addition, the amorphous carbon film was etched by 10 nm to 40 nm, approximately.

The next step was the removal of deposits attached on the sidewalls of the SiN film and of the SiO₂ film. For this purpose, a plasma processing was carried out under the conditions of an O₂ flow rate of 100 sccm, a source power of 300 W, and a pressure of 7 Pa. The conditions for the plasma processing were adjusted so that the etching amount of the resist film could be 10 nm.

Subsequently, the silicon substrate was dry-etched to form a concave portion. The etching gas used for this purpose was Cl₂ gas. In this case, no step was formed at the interface between the silicon substrate and the SiO₂ film, or, to be more precise, between the sidewalls of the silicon substrate and the sidewalls of the SiO₂ film. During this etching of the silicon substrate, the amorphous carbon film was also etched by 20 nm to 70 nm, but the SiN film was not made to be exposed.

After that, the amorphous carbon film was removed by oxygen plasma ashing. The conditions for the ashing were an O₂ flow rate of 3 slm, a microwave power of 3 kW, and a pressure of 200 Pa. The removal of the amorphous carbon film made the top surface of the SiN film exposed outside.

### COMPARATIVE EXAMPLE

A semiconductor device was fabricated following the same procedure except that the plasma processing to remove the deposits was not carried out. In this case, on the sidewalls of an opening portion formed in the SiN film, deposits of an approximately 5-nm thickness for each side were observed. The etching of the silicon substrate was carried out with the deposits still remaining, so that a step of an approximately 5-nm thickness was formed at the interface between the silicon substrate and the SiO₂ film.

What is claimed is:

1. A method of manufacturing a semiconductor device comprising:
forming a first film on a substrate that has a first layer on a surface of said substrate;
forming an opening portion in said first film;
carrying out a plasma processing and thus removing deposits attached on sidewalls of said opening portion; and
removing selectively said first layer by using said first film as a mask after removing said deposits.

2. The method of manufacturing a semiconductor device according to claim 1,
wherein said substrate is a silicon substrate,
said first layer is a part of said silicon substrate, and
a concave portion is formed in said silicon substrate by removing selectively said first layer.

3. The method of manufacturing a semiconductor device according to claim 2 in which said concave portion is a trench for isolating elements, further comprising:
forming an insulating film over said silicon substrate so as to bury said concave portion; and
removing a part of said insulating film, said part being formed outside of said concave portion.

4. The method of manufacturing a semiconductor device according to claim 1, wherein said first layer is a second film formed over said substrate.

5. The method of manufacturing a semiconductor device according to claim 1, wherein said first film includes a silicon-containing film.

6. The method of manufacturing a semiconductor device according to claim 5, wherein said first film is one of a SiN film, a SiO₂ film, and a laminated film of the SiN film and the SiO₂ film.

7. The method of manufacturing a semiconductor device according to claim 5, wherein said opening portion is formed by etching selectively said first film by at least using a gas containing a carbon atom and a fluorine atom in a molecule of said gas.

8. The method of manufacturing a semiconductor device according to claim 1, wherein said plasma processing is carried out by using a gas containing at least one of O₂, O₃, N₂, H₂, and NH₃.

9. The method of manufacturing a semiconductor device according to claim 1 further comprising:
forming a resist film having a predetermined pattern so as to be in contact with a surface of said first film,
wherein said opening portion is formed in said first film by using said resist film as a mask.

10. The method of manufacturing a semiconductor device according to claim 1 further comprising:
forming a carbon-containing film so as to be in contact with a surface of said first film;
forming a resist film having a predetermined pattern on said carbon-containing film; and
patterning said carbon-containing film by using said resist film as a mask,
wherein said opening portion is formed in said first film by using said carbon-containing film as a mask.

11. The method of manufacturing a semiconductor device according to claim 1 further comprising:
forming a carbon-containing film so as to be in contact with a surface of said first film;
forming an anti-reflective film made of an inorganic material on said carbon-containing film;
forming a resist film having a predetermined pattern on said anti-reflective film; and
patterning said anti-reflective film and said carbon-containing film by using said resist film as a mask,
wherein said opening portion is formed in said first film by using said carbon-containing film and said anti-reflective film as a mask.

12. The method of manufacturing a semiconductor device according to claim 10, wherein said carbon-containing film is an amorphous carbon film.

13. The method of manufacturing a semiconductor device according to claim 11, wherein said carbon-containing film is an amorphous carbon film.

14. The method of manufacturing a semiconductor device according to claim 9, wherein said plasma processing is carried out under the conditions that said resist film is etched by a thickness of not less than 5 nm but not more than 30 nm.

15. The method of manufacturing a semiconductor device according to claim 10, wherein said plasma processing is carried out under the conditions that, when an etching amount is converted into a thickness of said resist film to be etched, said resist film is etched by a thickness of not less than 5 nm but not more than 30 nm.

16. The method of manufacturing a semiconductor device according to claim 11, wherein said plasma processing is carried out under the conditions that, when an etching amount is converted into a thickness of said resist film to be etched, said resist film is etched by a thickness of not less than 5 nm but not more than 30 nm.
